(19) United States
(12) Patent Application Publication
(10) Pub. No.: US 2024/0047492 A1
(43) Pub. Date: Feb. 8, 2024

(54) DISPLAY DEVICE AND METHOD FOR MANUFACTURING THE SAME

(71) Applicant: Samsung Display Co., Ltd., Yongin-si (KR)

(72) Inventors: HONGMIN YOON, Yongin-si (KR); YUJIN KIM, Yongin-si (KR); DASOM KANG, Yongin-si (KR); SHIN TACK KANG, Yongin-si (KR); KISOO PARK, Yongin-si (KR); SEUNG JUN YU, Yongin-si (KR); JUNHAN LEE, Yongin-si (KR); KUNHEE JO, Yongin-si (KR)

(21) Appl. No.: 18/126,689

(22) Filed: Mar. 27, 2023

(30) Foreign Application Priority Data
Aug. 5, 2022 (KR) 10-2022-0098072

(51) Int. Cl. H01L 27/146

(52) U.S. Cl. CPC H01L 27/14621; H01L 27/14625

(57) ABSTRACT

A display device includes an upper substrate, a lower substrate opposite to the upper substrate, light emitting diodes on the lower substrate, a color conversion layer on the lower substrate and including a light transmission pattern in a first light emitting area, a first color conversion pattern in a second light emitting area, and a second color conversion pattern in a third light emitting area, a color filter layer under the upper substrate and including a first color filter in the first light emitting area and the light blocking area, a second color filter in the second light emitting area and the light blocking area, and a third color filter in the third light emitting area and having an island pattern shape, and a spacer in the light blocking area between the color filter layer and the color conversion layer and including a same material as the third color filter.

This application claims priority to Korean Patent Application No. 10-2022-0098072, filed on Aug. 5, 2022, and all the benefits accruing therefrom under 35 U.S.C. § 119, the content of which in its entirety is herein incorporated by reference.

### BACKGROUND

### 1. Field

Embodiments of the invention relate to a display device and method for manufacturing the display device.

### 2. Description of the Related Art

A flat panel display device is used as a display device replacing a cathode ray and due to characteristics such as light weight and thin shape. Representative examples of such flat panel display devices include a liquid crystal device (LCD) and an organic light emitting display device (OLED).

Recently, an organic light emitting display device including an organic light emitting diode and a color conversion layer has been researched. The color conversion layer may convert a wavelength of light provided from the organic light emitting diode. Accordingly, the organic light emitting display may emit light having a color different from that of incident light.

### SUMMARY

Embodiments provide a display device with improved display quality and improved manufacturing process efficiency.

Embodiments provide a method for manufacturing the display device.

A display device according to an embodiment includes an upper substrate, a lower substrate disposed opposite to the upper substrate, where first to third light emitting areas and a light blocking area surrounding the first to third light emitting areas are defined on each of the upper substrate and the lower substrate, a plurality of light emitting diodes disposed on the lower substrate, a color conversion layer including a light transmission pattern disposed in the first light emitting area on the lower substrate, a first color conversion pattern disposed in the second light emitting area on the lower substrate, and a second color conversion pattern disposed in the third light emitting area on the lower substrate, a color filter layer including a first color filter disposed in the first light emitting area and the light blocking area under the upper substrate, a second color filter disposed in the second light emitting area and the light blocking area under the upper substrate, and a third color filter disposed in the third light emitting area under the upper substrate and having an island pattern shape, and a spacer disposed in the light blocking area between the color filter layer and the color conversion layer, where the spacer includes a same material as the third color filter.

In an embodiment, the first color filter and the second color filter may overlap each other in the light blocking area.

In an embodiment, a planar shape of the third color filter may be a polygonal, a rhombic, a circular, a track-shaped, or an elliptical planar shape.

In an embodiment, a first opening and a second opening exposing a portion of the upper substrate may be defined through the first color filter, a third opening exposing a portion of the first color filter and a fourth opening exposing a portion of the upper substrate and overlapping the second opening may be defined through the second color filter, and the third color filter may be disposed in the second opening.

In an embodiment, the third color filter may be spaced apart from the light blocking area.

In an embodiment, the fourth opening may expose a portion of the second color filter and the third color filter may be disposed to cover the portion of the second color filter exposed through the fourth opening.

In an embodiment, the display device may further include a thin film encapsulation layer disposed on the lower substrate and covering the plurality of light emitting diodes and the color conversion layer may be disposed on the thin film encapsulation layer to directly contact the thin film encapsulation layer.

In an embodiment, the display device may further include a refractive layer disposed to cover the color filter layer and the spacer.

In an embodiment, the display device may further include a capping layer disposed to cover the color conversion layer and a refractive layer disposed to cover the capping layer.

In an embodiment, the first color filter may be a blue color filter which selectively transmits blue light, the second color filter may be a red color filter which selectively transmits red light, and the third color filter may be a green color filter which selectively transmits green light.

In an embodiment, the first color filter may be a blue color filter which selectively transmits blue light, the second color filter may be a green color filter which selectively transmits green light, and the third color filter may be a red color filter which selectively transmits red light.

A method of manufacturing a display device according to an embodiment includes providing a first color filter on an upper substrate, in which first to third light emitting areas and a light blocking area surrounding the first to third light emitting areas are defined, where the first color filter is disposed in the first light emitting area and the light blocking area, providing a second color filter on the upper substrate, where the second color filter is disposed in the second light emitting area and the light blocking area, providing a third color filter disposed in the third light emitting area and having an island pattern shape and a spacer disposed in the light blocking area, providing a color conversion layer on a lower substrate, where the first to third light emitting areas and the light blocking area are defined in the lower substrate, and the color conversion layer includes a light transmission pattern disposed in the first light emitting area on the lower substrate, a first color conversion pattern disposed in the second light emitting area on the lower substrate, and a second color conversion pattern disposed in the third light emitting area on the lower substrate, and bonding the upper substrate and the lower substrate to each other in a way such that the upper substrate is disposed opposite to the lower substrate.

In an embodiment, the spacer may be formed of the same material as the third color filter.

In an embodiment, after the bonding the upper substrate and the lower substrate to each other, the spacer may be disposed between the first and second color filters in the light blocking area and the color conversion layer.

In an embodiment, the first color filter and the second color filter may overlap each other in the light blocking area.

In an embodiment, the third color filter may have a polygonal, a rhombic, a circular, a track-shaped, or an elliptical planar shape.

In an embodiment, the first color filter may be a blue color filter which selectively transmits blue light, the second color filter may be a red color filter which selectively transmits red light, and the third color filter may be a green color filter which selectively transmits green light.

In an embodiment, the first color filter may be a blue color filter which selectively transmits blue light, the second color filter may be a green color filter which selectively transmits green light, and the third color filter may be a red color filter which selectively transmits red light.

In an embodiment, the method may further include providing a refractive layer to cover the third color filter and the spacer after the providing the third color filter and the spacer on the upper substrate.

In an embodiment, the method may further include providing a capping layer to cover the color conversion layer after the providing the third color filter and the spacer on the upper substrate, and providing a refractive layer to cover the capping layer after the providing the capping layer.

In the display device according to embodiments, the color conversion layer is included in the lower structure, such that a distance between the light emitting diodes and the color conversion layer may be decreased. Accordingly, light efficiency of the display device may be improved. Accordingly, display quality of the display device may be improved.

In such embodiments, the display device may include a color filter layer including a first color filter disposed in a first light emitting area and a light blocking area, a second color filter disposed in a second light emitting area and the light blocking area, and a third color filter disposed in a third light emitting area and having an island pattern shape. Accordingly, a gap between a lower structure and an upper structure may be reduced. Accordingly, display quality of the display device may be improved.

In addition, in the method of manufacturing the display device according to embodiments, a spacer may be formed together with the third color filter. In such embodiments, the spacer may include a same material as the third color filter. Accordingly, a separate mask process for forming the spacer may not be used. Thus, the efficiency of the manufacturing process of the display device may be improved.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a perspective view illustrating a display device according to an embodiment.

FIG. 2 is a cross-sectional view taken along line I-I′ of FIG. 1.

FIG. 3 is a plan view illustrating a display area of the display device of FIG. 1.

FIG. 4 is a cross-sectional view illustrating the display area of FIG. 3.

FIGS. 5 to 15 are views illustrating a manufacturing method of the display device of FIG. 1.

FIG. 16 is a cross-sectional view illustrating a display device according to an alternative embodiment.

FIG. 17 is a cross-sectional view illustrating a display device according to another alternative embodiment.

FIG. 18 is a cross-sectional view illustrating a display device according to still another alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the invention will be described in detail with reference to the accompanying drawings.

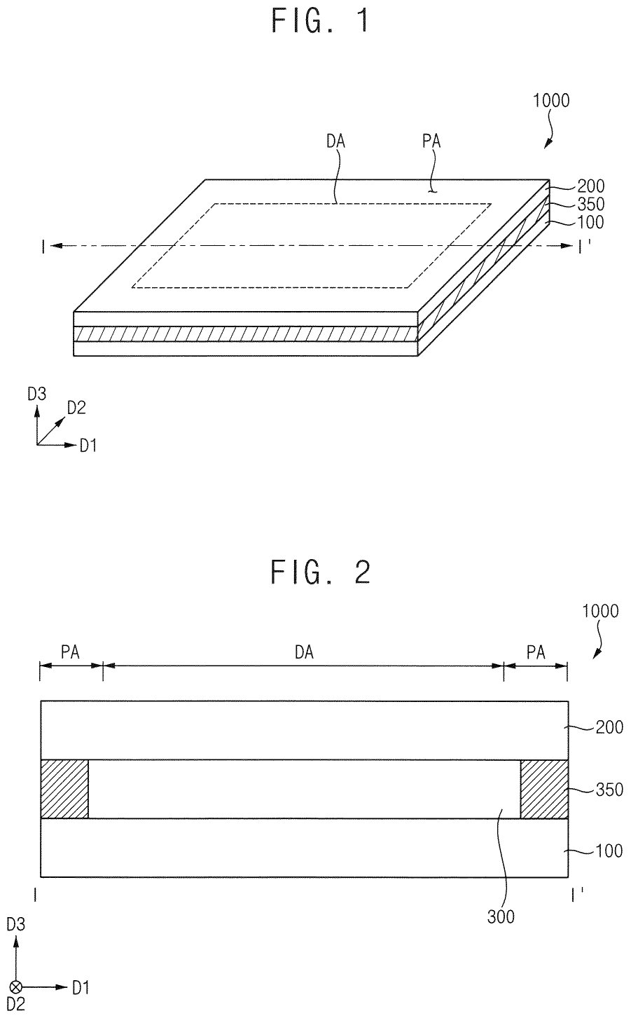

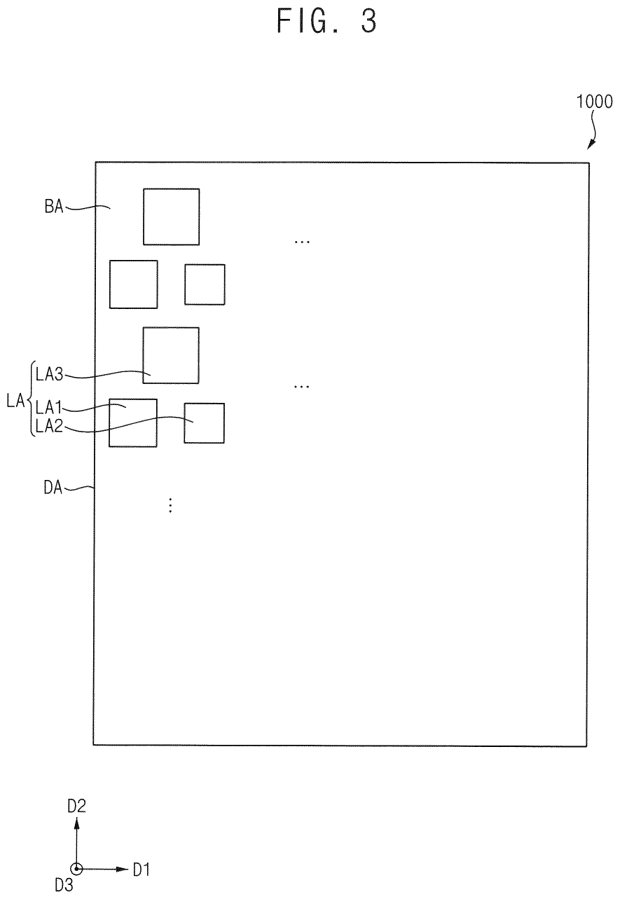

FIG. 1 is a perspective view illustrating a display device according to an embodiment, and FIG. 2 is a cross-sectional view taken along line I-I′ of FIG. 1.

Referring to FIGS. 1 and 2, an embodiment of the display device 1000 may include a lower structure 100, an upper structure 200, a filling layer 300 and a sealing member 350.

The display device 1000 may be divided into a display area DA and a peripheral area PA. The display area DA may display an image, and the peripheral area PA may be located around the display area DA. In an embodiment, for example, the peripheral area PA may surround the display area DA.

In an embodiment, the display device 1000 may have a rectangular shape on a plane. However, the invention is not necessarily limited thereto, and the display device 1000 may have various shapes on a plane. Herein, the plane may be defined from a first direction D1 and a second direction D2 intersecting the first direction D1. A third direction D3 may be perpendicular to the plane. The third direction D3 may be referred to as a front direction (or a thickness direction) of the display device 10.

The lower structure 100 may include a pixel array and a color conversion layer. Each pixel of the pixel array may include a light emitting diode for generating light based on a driving signal. The color conversion layer may convert a color of light emitted from the light emitting diode.

The upper structure 200 may be disposed on the lower structure 100. The upper structure 200 may face the lower structure 100. The upper structure 200 may include a color filter that transmits light having a specific color.

Detailed features of the lower structure 100 and the upper structure 200 will be described later.

The filling layer 300 may be disposed between the lower structure 100 and the upper structure 200. The filling layer 300 may act as a buffer against external pressure applied to the display device 1000. In an embodiment, for example, the filling layer 300 may maintain a gap between the lower structure 100 and the upper structure 200. The filling layer 300 may include a material capable of transmitting light. In an embodiment, for example, the filling layer 300 may include an organic material. In an embodiment, the organic material of the filling layer 300 may include at least one selected from silicone-based resins and epoxy-based resins. These may be used alone or in combination with each other. In an alternative embodiment, the filling layer 300 may be omitted.

The sealing member 350 may be disposed between the lower structure 100 and the upper structure 200 in the peripheral area PA. The sealing member 350 may be disposed along the edges of the lower structure 100 and the upper structure 200 in the peripheral area PA to surround the display area DA on a plane. In addition, the lower structure 100 and the upper structure 200 may be bonded to each other through the sealing member 350. The sealing member 350 may include an organic material. In an embodiment, for example, the sealing member 350 may include an epoxy resin or the like.

FIG. 3 is a plan view illustrating a display area of the display device of FIG. 1.

Referring to FIG. 3, in an embodiment, the display area DA may include (or be divided into) a plurality of light emitting areas LA and a light blocking area BA. In such an embodiment, the light emitting areas LA may include a first light emitting area LA1, a second light emitting area LA2, and a third light emitting area LA3.

Each of the first light emitting area LA1, the second light emitting area LA2, and the third light emitting area LA3 may be an area through which light emitted from the light emitting diode is emitted to the outside of the display device 1000. In an embodiment, for example, the first light emitting area LA1 may emit first light, the second light emitting area LA2 may emit second light, and the third light emitting area LA3 may emit third light. In an embodiment, the first light may be blue light, the second light may be red light, and the third light may be green light. However, the invention is not necessarily limited thereto, and for example, the light emitting areas LA may be combined to emit yellow, cyan, and magenta lights.

In an alternative embodiment, the light emitting areas LA may emit light of four or more colors. In an embodiment, for example, the light emitting areas LA may be combined to further emit at least one of yellow, cyan, and magenta lights in addition to red, green, and blue lights. Also, the light emitting areas LA may be combined to further emit white light.

On a plane, each of the first light emitting area LA1, the second light emitting area LA2, and the third light emitting area LA3 may be repeatedly arranged along a row direction and a column direction. In an embodiment, on a plane, the first light emitting area LA1, the second light emitting area LA2, and the third light emitting area LA3 may be repeatedly arranged along the first direction D1 and the second direction D2. In an embodiment, on a plane, the second light emitting area LA2 may be repeatedly arranged in the first row of the display area DA, and the first light emitting area LA1 and the third light emitting area LA2 may be arranged alternately with each other in the second row of the display area DA. However, the invention is not necessarily limited thereto, and in the display area DA, the light emitting areas LA may be arranged in various ways.

In an embodiment, each of the first light emitting area LA1, the second light emitting area LA2, and the third light emitting area LA3 may have different sizes (e.g., planar areas) from each other. In an embodiment, for example, the size of the third light emitting area LA3 may be smaller than the size of the first light emitting area LA1 and the size of the second light emitting area LA2, and the size of the second light emitting area LA2 may be greater than the size of the first light emitting region LA1. However, the invention is not necessarily limited thereto, and the sizes of the first to third light emitting areas LA1, LA2, and LA3 may be variously modified.

In an embodiment, each of the first light emitting area LA1, the second light emitting area LA2, and the third light emitting area LA3 may have a rectangular planar shape. However, the invention is not necessarily limited thereto, and each of the first light emitting area LA1, the second light emitting area LA2, and the third light emitting area LA3 may have various planar shapes. In an embodiment, for example, each of the first light emitting area LA1, the second light emitting area LA2, and the third light emitting area LA3 may have a polygonal planar shape other than a rectangular, a diamond, a circular, a track-shaped, or an elliptical planar shape, or the like.

The light blocking area BA may surround the light emitting areas LA on a plane. In an embodiment, the light blocking area BA may surround the first to third light emitting areas LA1, LA2, and LA3 on a plane. In an embodiment, for example, the light blocking area BA may have a grid shape on a plane. The light blocking area BA may block light emitted from the light emitting diode.

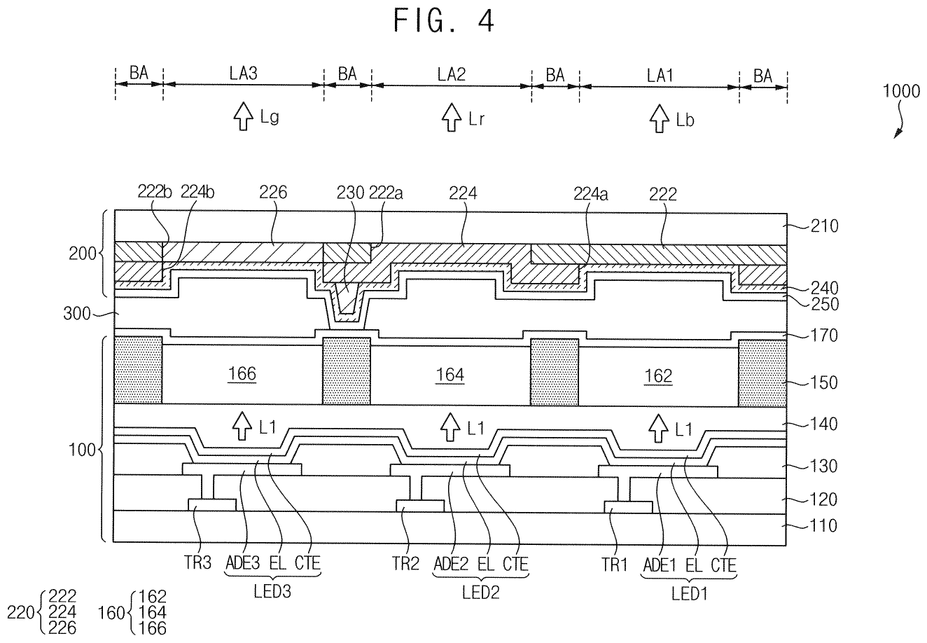

FIG. 4 is a cross-sectional view illustrating the display area of FIG. 3.

Referring to FIG. 4, as described above, an embodiment of the display device 1000 may include a lower structure 100, an upper structure 200 and a filling layer 300.

The lower structure 100 may include a lower substrate 110, first to third driving elements TR1, TR2, TR3, an insulating structure 120, a pixel defining layer 130, and first to third light emitting diodes LED1, LED2, LED3, a thin film encapsulation layer 140, a bank 150, a color conversion layer 160 and a first capping layer 170.

The lower substrate 110 may be an insulating substrate including or made of a transparent or opaque material. In an embodiment, the lower substrate 110 may include glass. In such an embodiment, the lower substrate 110 may be a rigid substrate. In an alternative embodiment, the lower substrate 110 may include plastic. In such an embodiment, the lower substrate 110 may be a flexible substrate. The lower substrate 110 may include the first to third light emitting areas LA1, LA2, and LA3 and the light blocking area BA, that is, the first to third light emitting areas LA1, LA2, and LA3 and the light blocking area BA may be defined in the lower substrate 110.

The first to third driving elements TR1, TR2, and TR3 may be disposed in the first to third light emitting areas LA1, LA2, and LA3, respectively, on the lower substrate 110. In an embodiment, each of the first to third driving elements TR1, TR2, and TR3 may include at least one thin film transistor and at least one capacitor. A channel layer of the thin film transistor may include an oxide semiconductor, a silicon semiconductor, or an organic semiconductor. In an embodiment, for example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, or the like.

In an embodiment, a buffer layer (not shown) may be disposed between the lower substrate 110 and the first to third driving elements TR1, TR2, and TR3. The buffer layer may prevent diffusion of impurities such as oxygen and moisture to the upper portion of the lower substrate 110 through the lower substrate 110. The buffer layer may include an inorganic insulating material such as a silicon compound or a metal oxide. In an embodiment the inorganic insulating material of the buffer layer may include at least one selected from silicon oxide (SiO), silicon nitride (SiN), silicon oxynitride (SiON), silicon oxycarbide (SiOC), silicon carbonitride (SiCN), aluminum oxide (AlO), and aluminum nitride. (AlN), tantalum oxide (TaO), hafnium oxide (HfO), zirconium oxide (ZrO), and titanium oxide (TiO). These may be used alone or in combination with each other. The buffer layer may have a single-layer structure or a multi-layer structure including a plurality of insulating layers.

The insulating structure 120 may cover the first to third driving elements TR1, TR2, and TR3. The insulating structure 120 may include a combination of an inorganic insulating layer and an organic insulating layer. In an embodiment, for example, the inorganic insulating layer may include at least one selected from silicon oxide, silicon nitride, silicon carbide, silicon oxynitride, silicon oxycarbide, and the like, and the organic insulating layer may include at least one selected from photoresist, polyacryl-based resin, polyimide-based resin, polyamide-based resin, siloxane-based resin, acrylic-based resin, epoxy-based resin, and the like. These may be used alone or in combination with each other.

First to third pixel electrodes ADE1, ADE2, and ADE3 may be disposed in the first to third light emitting areas LA1, LA2, and LA3, respectively, on the insulating structure 120. Each of the first to third pixel electrodes ADE1, ADE2, and ADE3 may include a conductive material such as a metal, an alloy, a conductive metal nitride, a conductive metal oxide, or a transparent conductive material. Each of the first to third pixel electrodes ADE1, ADE2, and ADE3 may have a single-layer structure or a multi-layer structure including a plurality of conductive layers.

the first to third pixel electrodes ADE1, ADE2, and ADE3 may be electrically connected to the first to third driving elements TR1, TR2, and TR3, respectively, through contact holes defined or formed in the insulating structure 120.

The pixel defining layer 130 may be disposed on the first to third pixel electrodes ADE1, ADE2, and ADE3. The pixel defining layer 130 may include an organic insulating material. In an embodiment, the organic insulating material of the pixel defining layer 130 may include at least one selected from photoresist, polyacryl-based resin, polyimide-based resin, polyamide-based resin, and siloxane-based resin, acrylic-based resin, epoxy-based resin, and the like. These may be used alone or in combination with each other. A pixel opening may be defined through the pixel defining layer 130 to expose at least a portion of each of the first to third pixel electrodes ADE1, ADE2, and ADE3.

An emission layer EL may be disposed on the portion of each of the first to third pixel electrodes ADE1, ADE2, and ADE3 exposed by the pixel opening of the pixel defining layer 130. The light emission layer EL may include an organic light emitting material. In an embodiment, the emission layer EL may be disposed on the first to third pixel electrodes ADE1, ADE2, and ADE3 and the pixel defining layer 130. In an alternative embodiment, the emission layer EL may be disposed only on the first to third pixel electrodes ADE1, ADE2, and ADE3.

In an embodiment, the emission layer EL may generate blue light. However, the invention is not necessarily limited thereto, and alternatively, the emission layer EL may generate red light or green light or may generate lights having different colors according to pixels.

In an embodiment, the emission layer EL may have a multilayer structure in which pluralities of layers are stacked. In an embodiment, for example, where the emission layer EL may generate blue light, the light emission layer EL may have a structure in which a plurality of blue organic light emission layers are stacked. In an alternative embodiment, the emission layer EL may have a multilayer structure in which pluralities of layers emitting light of different colors are stacked. In an embodiment, for example, where the emission layer EL generates blue light, the emission layer EL may have a structure in which a plurality of blue organic light emission layers and an organic light emission layer for emitting light of a color other than blue are stacked.

In an embodiment, functional layers such as a hole injection layer, a hole transport layer, an electron transport layer, and an electron injection layer may be disposed above and/or below the light emission layer EL.

A common electrode CTE may be disposed on the emission layer EL. The emission layer EL may emit light based on a voltage difference between a corresponding one of the first to third pixel electrodes ADE1, ADE2, and ADE3 and the common electrode CTE. The common electrode CTE may include a conductive material such as a metal, an alloy, a conductive metal nitride, a conductive metal oxide, or a transparent conductive material. The common electrode CTE may have a single-layer structure or a multi-layer structure including a plurality of conductive layers. In an embodiment, the common electrode CTE may continuously extend over (or commonly cover) a plurality of pixels.

The first pixel electrode ADE1, the emission layer EL, and the common electrode CTE may form (or collectively define) the first light emitting diode LED1 and the second pixel electrode ADE2, the emission layer EL, and the common electrode CTE may form the second light emitting diode LED2, and the third pixel electrode ADE3, the emission layer EL, and the common electrode CTE may form the third light emitting diode LED3. In an embodiment, the first light emitting diode LED1 may be disposed in the first light emitting area LA1, the second light emitting diode LED2 may be disposed in the second light emitting area LA2, and the third light emitting diode LED3 may be disposed in the third light emitting area LA3.

The thin film encapsulation layer 140 may be disposed on the common electrode CTE. The thin film encapsulation layer 140 may prevent impurities, moisture, and the like from permeating the first to third light emitting diodes LED1, LED2, and LED3 from the outside. The thin film encapsulation layer 140 may include at least one inorganic encapsulation layer and at least one organic encapsulation layer. In an embodiment, for example, the inorganic encapsulation layer may include at least one selected from silicon oxide, silicon nitride, silicon oxynitride, and the like, and the organic encapsulation layer may include a polymer cured material such as polyacrylate. In an embodiment, the thin film encapsulation layer 140 may include a first inorganic encapsulation layer disposed on the common electrode CTE, an organic encapsulation layer disposed on the first inorganic encapsulation layer, and a second inorganic encapsulation layer disposed on the organic encapsulation layer.

The bank 150 may be disposed on the thin film encapsulation layer 140. The bank 150 may surround the color conversion layer 160. The bank 150 may provide a space for accommodating an ink composition or an organic composition in the process of forming a first color conversion pattern 164, a second color conversion pattern 166, and a light transmission pattern 162. Accordingly, the bank 150 may have a grid shape or a matrix shape on a plane.

In an embodiment, the bank 150 may include an organic material. In an embodiment, the bank 150 may further include a light blocking material. In an embodiment, for example, the bank 150 may include a light blocking material such as black pigment, dye, or carbon black. The bank 150 may overlap the light blocking area BA.

The color conversion layer 160 may be disposed on the thin film encapsulation layer 140. The color conversion layer 160 may be surrounded by the bank 150. In an embodiment, the color conversion layer 160 may convert light emitted from the first to third light emitting diodes LED1, LED2, and LED3 into light having a specific color. In an embodiment, for example, the color conversion layer 160 may include wavelength conversion particles.

The color conversion layer 160 may include the light transmission pattern 162, the first color conversion pattern 164 and the second color conversion pattern 166. In an embodiment, the light transmission pattern 162, the first color conversion pattern 164, and the second color conversion pattern 166 may be disposed in the first to third light emitting areas LA1, LA2, and LA3, respectively. In an embodiment, for example, the light transmission pattern 162 may be disposed in the first light emitting area LA1, the first color conversion pattern 164 may be disposed in the second light emitting area LA2, and the second color conversion pattern 166 may be disposed in the third light emitting area LA3.

In an embodiment, the light transmission pattern 162 may transmit the incident light L1 generated from the first light emitting diode LED1 without converting the color (or wavelength) thereof. In an embodiment, the incident light L1 may be blue light having a maximum emission peak wavelength of about 380 nanometers (nm) to about 480 nm. In other words, the light transmission pattern 162 may emit blue light Lb having substantially the same wavelength as the incident light L1. In an embodiment, the light transmission pattern 162 may include a first photosensitive polymer and a first scatter.

The first scatter may increase an optical path by scattering the incident light L1 without substantially changing the wavelength of the incident light L1. The first scatter may include a metal oxide. In an embodiment, the metal oxide of the first scatter may include at least one selected from TiO₂, ZrO₂, Al₂O₃, In₂O₃, ZnO, SnO₂, Sb₂O₃, and ITO. These may be used alone or in combination with each other.

The first scatter may be dispersed in the first photosensitive polymer. In an embodiment, for example, the photosensitive polymer may include at least one selected from an epoxy-based resin, an acrylic-based resin, a phenol-based resin, a melamine-based resin, a cardo-based resin, an imide-based resin, and the like.

In an embodiment, the first color conversion pattern 164 may convert incident light L1 generated from the second light emitting diode LED2 into red light Lr. In an embodiment, for example, the first color conversion pattern 164 may include a second photosensitive polymer, a second scatter, and a first wavelength conversion particle. In an embodiment, the second photosensitive polymer and the second scatter of the first color conversion pattern 164 may be substantially the same as the first photosensitive polymer and the first scatter of the light transmission pattern 162.

In an embodiment, the first wavelength conversion particle may include a quantum dot that absorbs blue light and emits red light. The quantum dot may be defined as a semiconductor material having nanocrystals. The quantum dot may have a specific band gap depending on its composition and size. Accordingly, the quantum dots may absorb the incident light L1 and emit light having a different wavelength from the incident light L1. In an embodiment, for example, the quantum dot may have a diameter of about 100 nm or less, and may specifically have a diameter of about 1 nm to about 20 nm. In an embodiment, for example, the first wavelength conversion particle of the first color conversion pattern 164 may include quantum dot that absorb blue light and emit red light Lr.

In an embodiment, the second color conversion pattern 166 may convert incident light L1 generated from the third light emitting diode LED3 into green light Lg. In an embodiment, for example, the second color conversion pattern 166 may include a third photosensitive polymer, a third scatter, and a second wavelength conversion particle. In an embodiment, the third photosensitive polymer and the third scatter of the second color conversion pattern 166 may be substantially the same as the first photosensitive polymer and the first scatter of the light transmission pattern 162. In an embodiment, the second wavelength conversion particle may include a quantum dot. In an embodiment, for example, the second color conversion particles may include quantum dot that absorb blue light and emit green light Lg.

According to embodiments, as the color conversion layer 160 is included in the lower structure 100, a distance between the light emitting diodes LED1, LED2, and LED3 and the color conversion layer 160 may be shortened. Accordingly, the density of the incident light L1 incident on the color conversion layer 160 may increase, the conversion rate of the incident light L1 may increase, and the light efficiency of the display device 1000 may be improved. Accordingly, display quality of the display device 1000 may be improved.

The first capping layer 170 may be disposed on the bank 150 and the color conversion layer 160. In an embodiment, for example, the first capping layer 170 may be disposed to surround the bank 150 and the color conversion layer 160. In an embodiment, the first capping layer 170 may include silicon oxide, silicon nitride, silicon carbide, silicon oxynitride, silicon oxycarbide, or the like. These may be used alone or in combination with each other.

The upper structure 200 may be disposed to face (or opposite to) the lower structure 100. In an embodiment, for example, the upper structure 200 may be disposed in the third direction D3 from the lower structure 100. In an embodiment, the upper structure 200 may include an upper substrate 210, a color filter layer 220, a spacer 230, a refractive layer 240 and a second capping layer 250.

The upper substrate 210 may be an insulating substrate including or made of a transparent or opaque material. In an embodiment, the upper substrate 210 may include glass. In such an embodiment, the upper substrate 210 may be a rigid substrate. In an alternative embodiment, the upper substrate 210 may include plastic. In such an embodiment, the upper substrate 210 may be a flexible substrate. The upper substrate 210 may include the first to third light emitting areas LA1, LA2, and LA3 and the light blocking area BA, that is, the first to third light emitting areas LA1, LA2, and LA3 and the light blocking area BA are defined in the upper substrate 210.

The color filter layer 220 may be disposed below the upper substrate 210. The color filter layer 220 may include a first color filter 222, a second color filter 224 and a third color filter 226.

The first color filter 222 may be disposed in the first light emitting area LA1 and the light blocking area BA. In an embodiment, the first color filter 222 may be entirely disposed in the light blocking area BA, that is, to overlap an entire portion of the light blocking area BA. In an embodiment, a first opening 222a and a second opening 222b may be defined through the first color filter 222. Each of the first opening 222a and the second opening 222b may expose a portion of the upper substrate 210. In an embodiment, the first opening 222a may overlap the second light emitting area LA2, and the second opening 222b may overlap the third light emitting area LA3.

The second color filter 224 may be disposed in the second light emitting area LA2 and the light blocking area BA. In an embodiment, the second color filter 224 may be disposed while filling the first opening 222a. In an embodiment, the second color filter 224 may be entirely disposed in the light blocking area BA. In an embodiment, a third opening 224a and a fourth opening 224b may be defined through the second color filter 224. The third opening 224a may expose a portion of the first color filter 222, and the fourth opening 224b may expose a portion of the upper substrate 210. In an embodiment, the third opening 224a may overlap the first light emitting area LA1 and the fourth opening 224b may overlap the third light emitting area LA3. In such an embodiment, the fourth opening 224b may overlap the second opening 222b.

In an embodiment, the first opening 222a of the first color filter 222 may correspond to the second light emitting area LA2, and the second opening 222b of the first color filter 222 may correspond to the third light emitting area LA3, and the third opening 224a of the second color filter 224 may correspond to the first light emitting area LA1. Accordingly, the first color filter 222 may define the second light emitting area LA2 and the third light emitting area LA3, and the second color filter 224 may define the first light emitting area LA1.

In an embodiment, the first color filter 222 and the second color filter 224 may overlap each other in the light blocking area BA. Accordingly, color mixing between the adjacent first to third light emitting areas LA1, LA2, and LA3 may be effectively prevented.

In an embodiment, each of the first opening 222a, the second opening 222b, the third opening 224a, and the fourth opening 224b may have a rectangular planar shape. However, the invention is not necessarily limited thereto, and each of the first opening 222a, the second opening 222b, the third opening 224a, and the fourth opening 224b may have various planar shapes. In an embodiment, for example, each of the first opening 222a, the second opening 222b, the third opening 224a, and the fourth opening 224b may have a polygonal planar shape other than a rectangular, a rhombic, a circular, a track-shaped, an elliptical planar shape, or the like.

The third color filter 226 may be disposed in the third light emitting area LA3. In an embodiment, the third color filter 226 may have an island pattern shape. In an embodiment, for example, the third color filter 226 may be disposed in the second opening 222b of the first color filter 222. In an embodiment, the third color filter 226 may be disposed to be spaced apart from (or not to overlap) the light blocking area BA. However, the invention is not necessarily limited thereto.

In an embodiment, the third color filter 226 may have a rectangular planar shape. However, the invention is not necessarily limited thereto, and the planar shape of the third color filter 226 may be variously determined according to the planar shape of the second opening 222b. In an embodiment, for example, according to the planar shape of the second opening 222b, the third color filter 226 may have a polygonal planar shape other than a rectangular, a rhombic, a circular, a track-shaped, an elliptical planar shape, or the like.

Each of the first color filter 222, the second color filter 224, and the third color filter 226 may selectively transmit light of a different color. In an embodiment, the first color filter 222 may be a blue color filter that selectively transmits the blue light Lb, the second color filter 224 may be a red color filter that selectively transmits the red light Lr, and the third color filter 226 may be a green color filter that selectively transmits the green light Lg.

In an embodiment, the first light emitting area LA1 may emit the blue light Lb, the second light emitting area LA2 may emit the red light Lr, and the third light emitting area LA3 may emit the green light Lg. However, the invention is not necessarily limited thereto, and the color of light selectively transmitted by each of the first to third color filters 222, 224, and 226 may be variously modified.

The spacer 230 may be disposed below the color filter layer 220. The spacer 230 may be disposed in the light blocking area BA. In such an embodiment, the spacer 230 may be disposed in the light blocking area BA between the color conversion layer 160 and the color filter layer 220. In an embodiment, for example, the spacer 230 may be disposed to overlap the first color filter 222 and the second color filter 224 in the light blocking area BA. In an embodiment, as shown in FIG. 4, a single spacer 230 is disposed between the second light emitting area LA2 and the third light emitting area LA3 in cross section, but the invention is not necessarily limited thereto. In an alternative embodiment, for example, a plurality of spacers 230 may be formed between the second light emitting area LA2 and the third light emitting area LA3. In an embodiment, the position where the spacer 230 is formed may be variously determined in the light blocking area BA. The spacer 230 may maintain a gap between the lower structure 100 and the upper structure 200.

In an embodiment, the spacer 230 may be formed together with the third color filter 226. In an embodiment, for example, the third color filter 226 and the spacer 230 may be formed through a single exposure and development process using a single exposure mask. In such an embodiment, the spacer 230 may include a same material as the third color filter 226. In an embodiment, for example, where the third color filter 226 is a green color filter that selectively transmits the green light Lg, the spacer 230 may include color filter composition including a green dye, a green pigment, a green dye, and/or a green pigment.

The refractive layer 240 may be disposed to surround the color filter layer 220 and the spacer 230. The refractive layer 240 may adjust a traveling path of light incident from the bottom toward the third direction D3. The refractive layer 240 may have a relatively lower refractive index than the layers positioned therearound or adjacent thereto. In an embodiment, the refractive layer 240 may be formed using an organic material. However, the invention is not necessarily limited thereto, and in an alternative embodiment, the refractive layer 240 may include an inorganic material.

The second capping layer 250 may be disposed under the refractive layer 240. In an embodiment, for example, the second capping layer 250 may be disposed to surround or cover the refractive layer 240. In an embodiment, the second capping layer 250 may include silicon oxide, silicon nitride, silicon carbide, silicon oxynitride, silicon oxycarbide, or the like. These may be used alone or in combination with each other. In an alternative embodiment, the second capping layer 250 may be omitted.

According to embodiments, the display device 1000 may include the first color filter 222 disposed in the first light emitting area LA1 and the light blocking area BA, the second color filter 224 disposed in the second light emitting area LA2 and the light blocking area BA, and the third color filter 226 disposed in the third light emitting area LA3 and having an island pattern shape. Accordingly, a gap between the lower structure 100 and the upper structure 200 may be reduced. Accordingly, display quality of the display device 1000 may be improved.

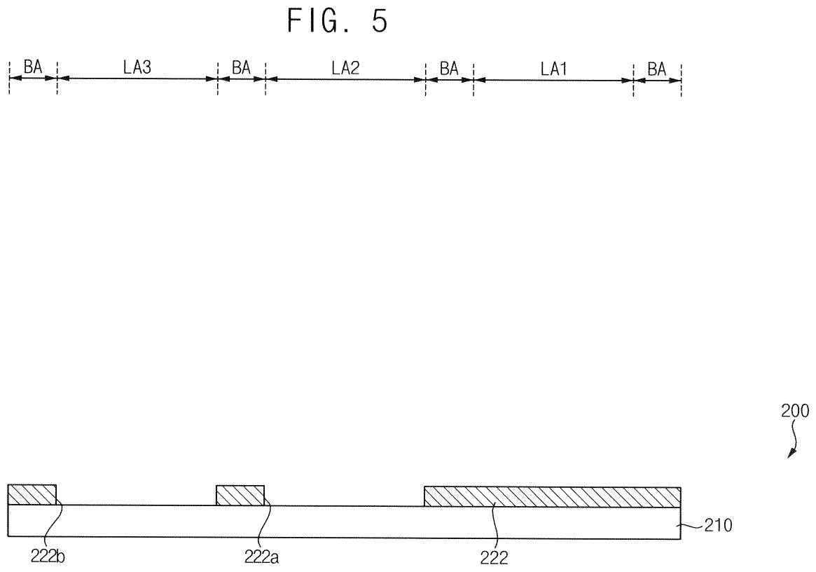

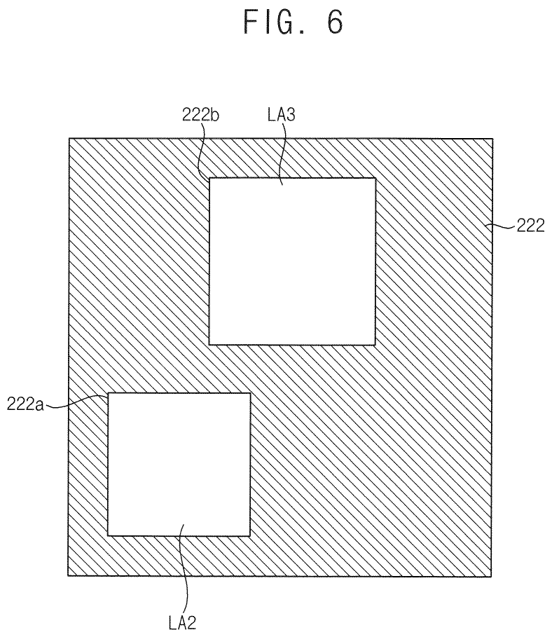

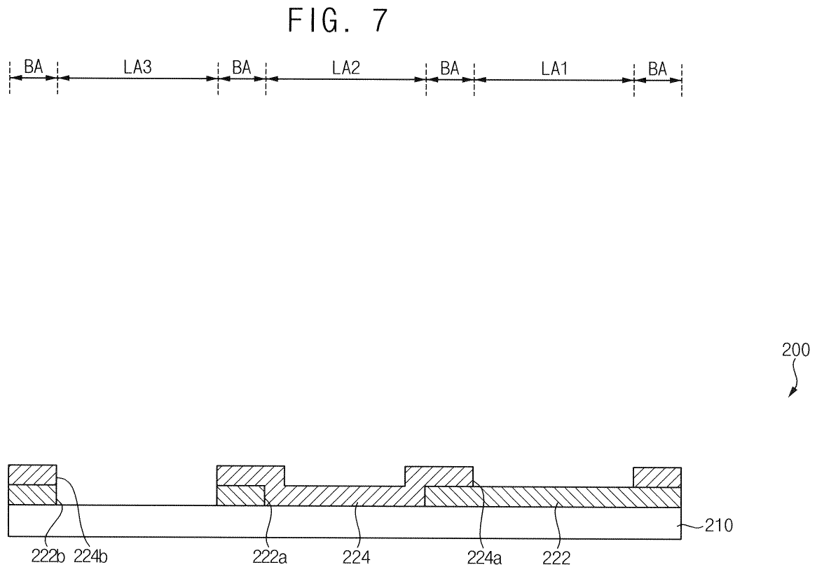

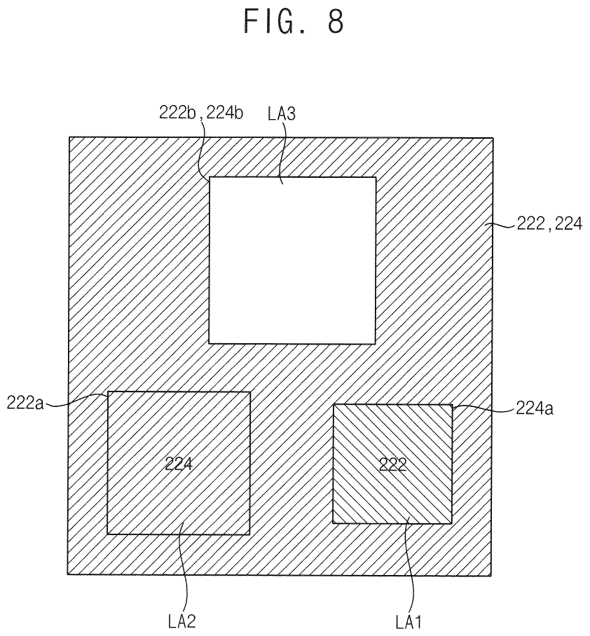

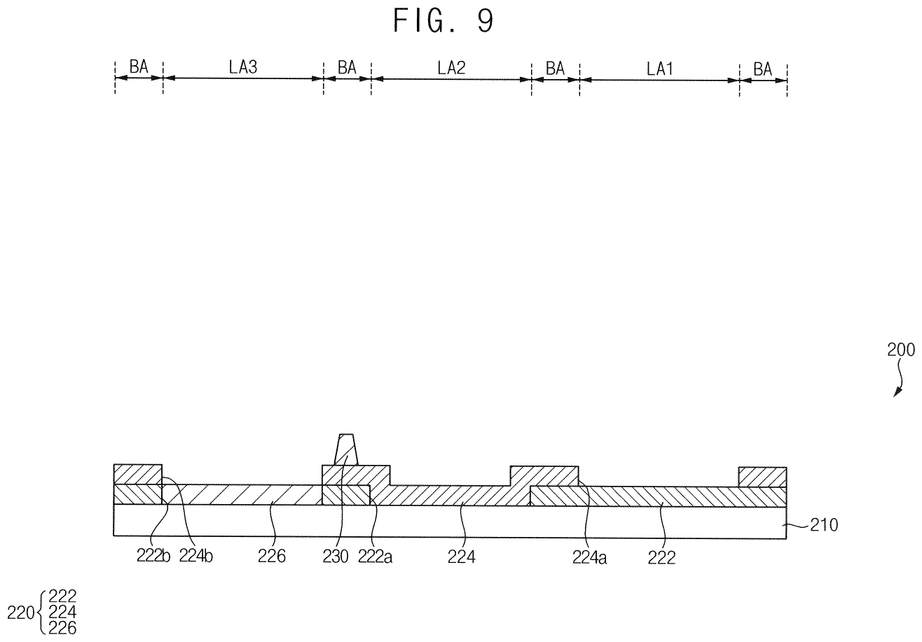

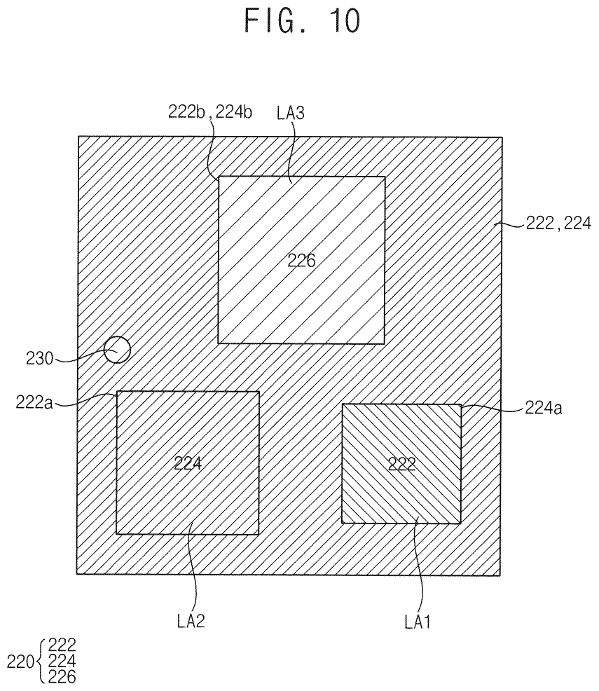

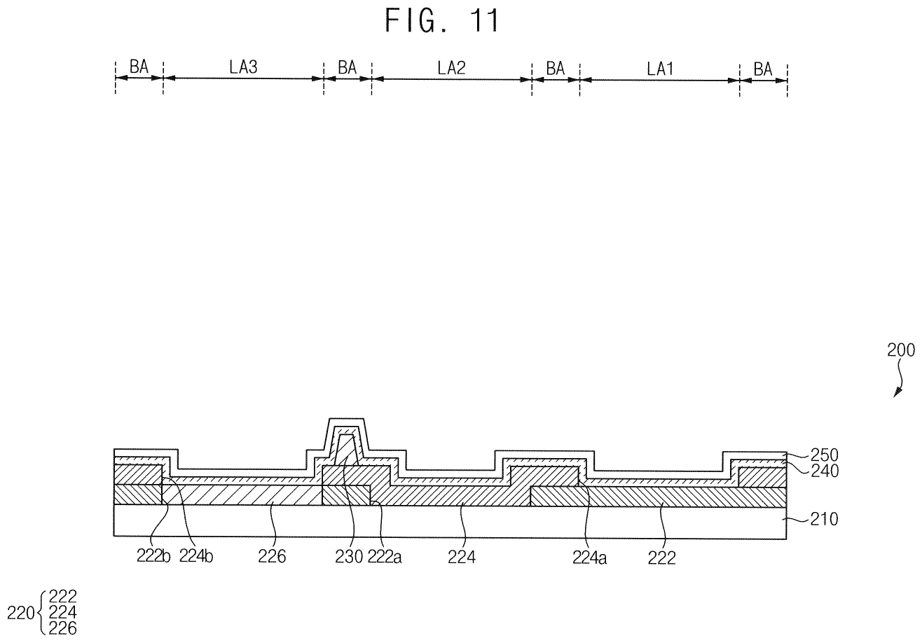

FIGS. 5 to 15 are views illustrating a manufacturing method of the display device of FIG. 1. Particularly, FIG. 6 is a schematic plan view illustrating the upper structure of FIG. 5, FIG. 8 is a schematic plan view illustrating the upper structure of FIG. 7, and FIG. 10 is a schematic plan view illustrating the upper structure of FIG. 9.

Referring to FIGS. 5 and 6, the first color filter 222 may be provided or formed on the upper substrate 210. The first color filter 222 may be disposed in the first light emitting area LA1 and the light blocking area BA. In an embodiment, a portion of the first color filter 222 may be formed in the first light emitting area LA1 and a remaining portion of the first color filter 222 may be entirely formed in the light blocking area BA.

In an embodiment, the first opening 222a corresponding to the second light emitting area LA2 and the second opening 222b corresponding to the third light emitting area LA3 may be formed through the first color filter 222. Accordingly, the first color filter 222 may define the second light emitting area LA2 and the third light emitting area LA3.

In an embodiment, the first color filter 222 may be a blue color filter that selectively transmits blue light. In an embodiment, for example, the first color filter 222 may be formed from a color filter composition including a blue dye, a blue pigment, a blue dye, and/or a blue pigment.

Referring to FIGS. 7 and 8, the second color filter 224 may be formed on the upper substrate 210 and the first color filter 222.

The second color filter 224 may be provided in the second light emitting area LA2 and the light blocking area BA. In an embodiment, a portion of the second color filter 224 may be formed in the second light emitting area LA2, and a remaining portion of the second color filter 224 may be entirely formed in the light blocking area BA. Accordingly, the first color filter 222 and the second color filter 224 may overlap each other in the blocking area BA.

In an embodiment, the third opening 224a corresponding to the first light emitting area LA1 and the fourth opening 224b corresponding to the third light emitting area LA3 may be formed through the second color filter 224. In an embodiment, the fourth opening 224b may overlap the second opening 222b of the first color filter 222. Accordingly, the second color filter 224 may define the first light emitting area LA1 and the third light emitting area LA3.

In an embodiment, the second color filter 224 may be a red color filter that selectively transmits red light. In an embodiment, for example, the second color filter 224 may be formed from (or using) a color filter composition including a red dye, a red pigment, a red dye and/or a red pigment.

Referring to FIGS. 9 and 10, the third color filter 226 may be provided or formed on the upper substrate 210 and the spacer 230 may be provided or formed on the second color filter 224. In an embodiment, the third color filter 226 and the spacer 230 may be formed through a single exposure and development process using a single exposure mask.

The third color filter 226 may be provided in the third light emitting area LA3. In an embodiment, the third color filter 226 may be formed to have an island pattern shape. In an embodiment, for example, the third color filter 226 may be provided in the second opening 222b of the first color filter 222. In an embodiment, the third color filter 226 may be formed to be spaced apart from the light blocking area BA. However, the invention is not necessarily limited thereto.

In an embodiment, the third color filter 226 may be formed to have a rectangular planar shape. However, the invention is not necessarily limited thereto, and the planar shape of the third color filter 226 may be variously determined based on the planar shape of the second opening 222b. In an embodiment, for example, the third color filter 226 may have a polygonal planar shape other than a rectangular, a rhombic, a circular, a track-shaped, an elliptical planar shape, or the like, to correspond to the planar shape of the second opening 222b.

In an embodiment, the third color filter 226 may be a green color filter that selectively transmits green light. In an embodiment, for example, the third color filter 226 may be formed from a color filter composition including a green dye, a green pigment, a green dye and/or a green pigment.

Accordingly, the color filter layer 220 including the first color filter 222, the second color filter 224, and the third color filter 226 may be formed on the upper substrate 210. In an embodiment, the first color filter 222, the second color filter 224, and the third color filter 226 may be sequentially formed as described above.

The spacer 230 may be provided in the light blocking area BA. Accordingly, the spacer 230 may be formed to overlap the first color filter 222 and the second color filter 224 in the blocking area BA. In an embodiment, as shown in FIG. 10, the spacer 230 is formed in the upper left portion of the second light emitting area LA2 on a plane and has a circular planar shape, but the invention is not necessarily limited thereto. In an embodiment, a position where the spacer 230 is formed may be variously determined in the light blocking area BA. In addition, the spacer 230 may have a polygonal, a rhombic, a track-shaped, an elliptical planar shape, or the like.

In an embodiment, as described above, the spacer 230 may be formed together with the third color filter 226. In such an embodiment, the spacer 230 may be formed of a same material as the third color filter 226. In an embodiment, for example, where the third color filter 226 is a green color filter that selectively transmits green light, the spacer 230 may be formed from a color filter composition including a green dye, a green pigment, a green dye and/or a green pigment.

Referring to FIG. 11, the refractive layer 240 may be provided or formed on the color filter layer 220 and the spacer 230. In an embodiment, for example, the refractive layer 240 may be formed to surround the color filter layer 220 and the spacer 230. After that, the second capping layer 250 may be formed on the refractive layer 240. In an embodiment, for example, the second capping layer 250 may be formed to surround the refractive layer 240.

Accordingly, the upper structure 200 including the upper substrate 210, the color filter layer 220, the spacer 230, the refractive layer 240 and the second capping layer 250 may be formed.

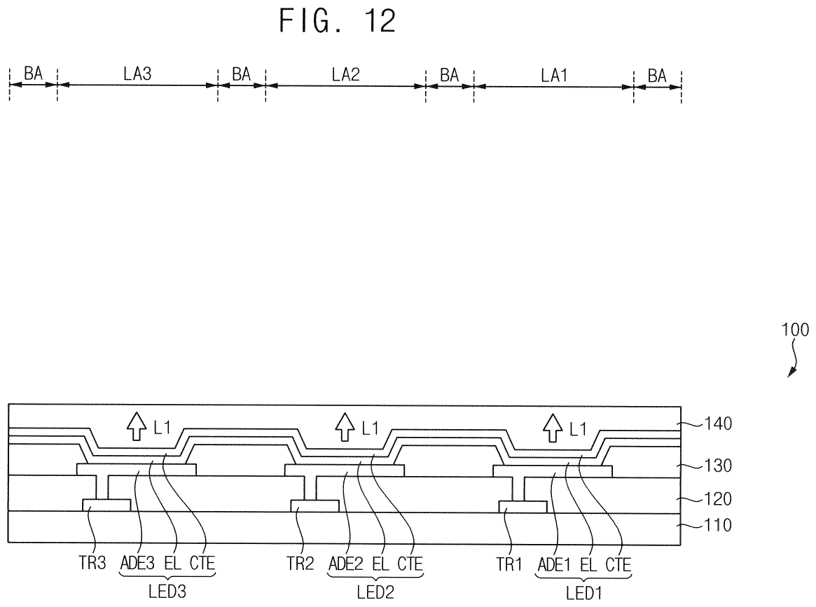

Referring to FIG. 12, the first to third driving elements TR1, TR2, TR3 and the insulating structure 120 may be provided or formed on the lower substrate 110. The insulating structure 120 may be formed to cover the first to third driving elements TR1, TR2, and TR3. Subsequently, the first to third pixel electrodes ADE1, ADE2, and ADE3 may be formed on the insulating structure 120. The first to third pixel electrodes ADE1, ADE2, and ADE3 may be electrically connected to the first to third driving elements TR1, TR2, and TR3, respectively, through contact holes formed in the insulating structure 120. Subsequently, the pixel defining layer 130 may be provided or formed on the insulating structure 120 on which the first to third pixel electrodes ADE1, ADE2, and ADE3 are formed. In an embodiment, the pixel opening exposing the first to third pixel electrodes ADE1, ADE2, and ADE3 may be formed through the pixel defining layer 130. Subsequently, the emission layer EL may be provided or formed on the first to third pixel electrodes ADE1, ADE2, and ADE3 exposed by the pixel opening of the pixel defining layer 130. In an embodiment, the emission layer EL may be provided on the first to third pixel electrodes ADE1, ADE2, and ADE3 and the pixel defining layer 130. Subsequently, the common electrode CTE may be provided or formed on the emission layer EL. In an embodiment, the common electrode CTE may continuously extend or commonly provided over a plurality of pixels. The first to third pixel electrodes ADE1, ADE2, and ADE3, the emission layer EL, and the common electrode CTE may form the first to third light emitting diodes LED1, LED2, and LED3. Subsequently, the thin film encapsulation layer 140 covering the first to third light emitting diodes LED1, LED2, and LED3 may be formed.

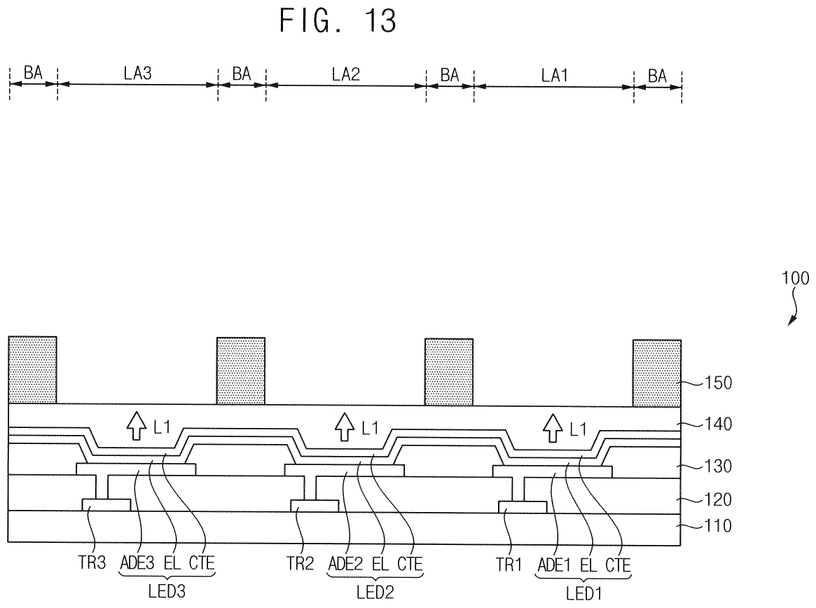

Referring to FIG. 13, the bank 150 may be provided or formed on the thin film encapsulation layer 140. The bank 150 may be disposed in the blocking area BA. The bank 150 may provide a space for accommodating an ink composition or an organic composition in the process of forming the color conversion layer 160. Accordingly, the bank 150 may have a grid shape or a matrix shape on a plane.

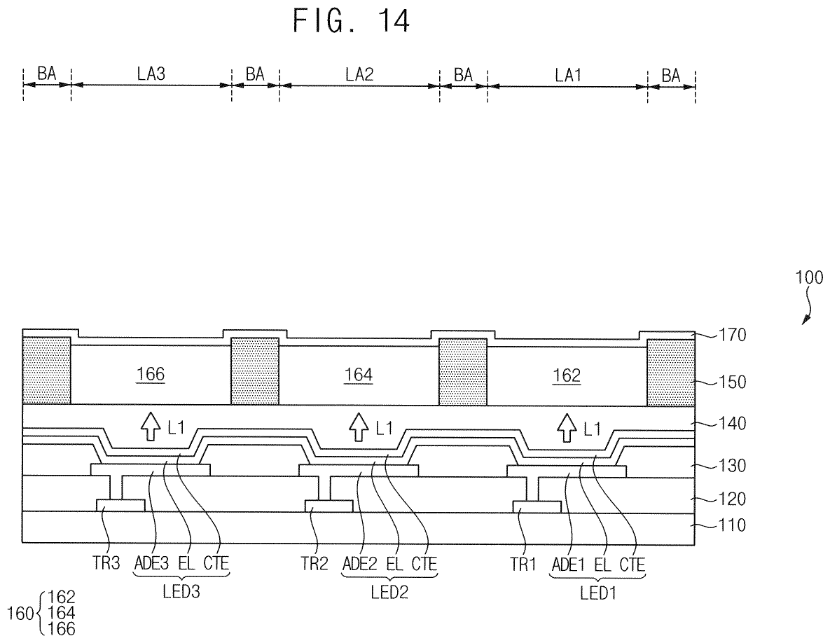

Referring to FIG. 14, the color conversion layer 160 filling the space of the bank 150 may be formed. In an embodiment, the color conversion layer 160 may include the light transmission pattern 162, the first color conversion pattern 164 and the second color conversion pattern 166. The light transmission pattern 162 may be disposed in the first light emitting area LA1, the first color conversion pattern 164 may be disposed in the second light emitting area LA2, and the second color conversion pattern 166 may be disposed in the third light emitting area.

In an embodiment, each of the light transmission pattern 162, the first color conversion pattern 164, and the second color conversion pattern 166 may be formed using an inkjet printing process. However, the invention is not necessarily limited thereto, and each of the light transmission pattern 162, the first color conversion pattern 164, and the second color conversion pattern 166 may be formed through a developing process after coating a photosensitive material.

After that, the first capping layer 170 may be formed on the bank 150 and the color conversion layer 160. In an embodiment, for example, the first capping layer 170 may be formed to surround the bank 150 and the color conversion layer 160.

Accordingly, the lower structure 100 including the lower substrate 110, the first to third driving elements TR1, TR2, TR3, the insulating structure 120, the pixel defining layer 130, and the first to third light emitting diodes LED1, LED2, LED3, the thin film encapsulation layer 140, the bank 150, the color conversion layer 160, and the first capping layer 170 may be formed.

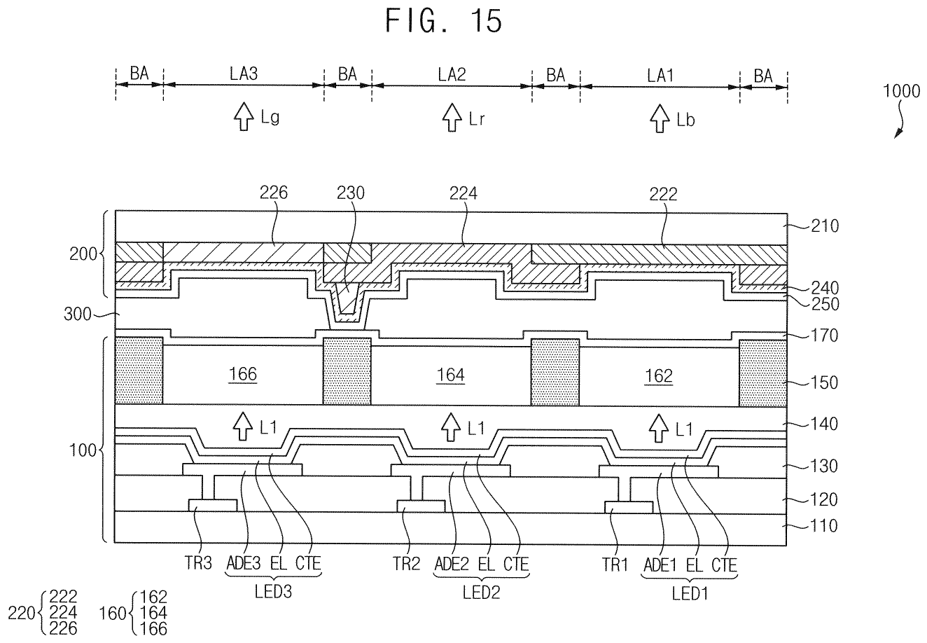

Referring to FIG. 15, the lower structure 100 and the upper structure 200 may be bonded to each other. The lower structure 100 and the upper structure 200 may be bonded to each other through the sealing member 350 (as shown in FIG. 2). Accordingly, the lower structure 100 and the upper structure 200 may be disposed to face each other. In an embodiment, for example, the upper structure 200 may be disposed in the third direction D3 from the lower structure 100. Accordingly, in the display device 1000, the spacer 230 may be disposed in the light blocking area BA between the color filter layer 220 and the color conversion layer 160. Accordingly, the spacer 230 may maintain a gap between the lower structure 100 and the upper structure 200.

In an embodiment, the filling layer 300 may be disposed between the lower structure 100 and the upper structure 200. In such an embodiment, the filling layer 300 may be disposed between the color conversion layer 160 and the color filter layer 220. The filling layer 300 may maintain a gap between the lower structure 100 and the upper structure 200. In an embodiment, the filling layer 300 may be formed of an organic material. In an embodiment, the material of the filling layer 300 may include at least one selected from silicone-based resins and epoxy-based resins. These may be used alone or in combination with each other. In another embodiment, the filling layer 300 may be omitted.

According to embodiments, the color conversion layer 160 is included in the lower structure 100, such that a distance between the light emitting diodes LED1, LED2, and LED3 and the color conversion layer 160 may be shortened. Accordingly, light efficiency of the display device 1000 may be improved. Accordingly, display quality of the display device 1000 may be improved.

In such embodiments, the display device 1000 may include the first color filter 222 disposed in the first light emitting area LA1 and the light blocking area BA, the second color filter 224 disposed in the second light emitting area LA2 and the light blocking area BA, and the third color filter 226 disposed in the third light emitting area LA3 and having an island pattern shape. Accordingly, a gap between the lower structure 100 and the upper structure 200 may be reduced. Accordingly, display quality of the display device 1000 may be improved.

In such embodiment, the spacer 230 may be formed together with the third color filter 226. Accordingly, a separate mask process for forming the spacer 230 may not be used. Accordingly, the efficiency of the manufacturing process of the display device 1000 may be improved.

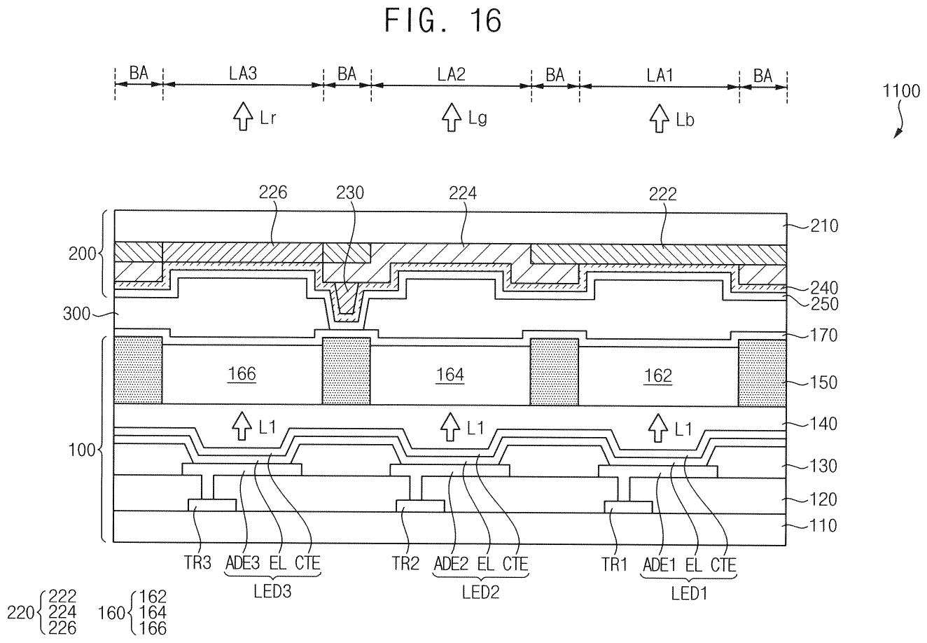

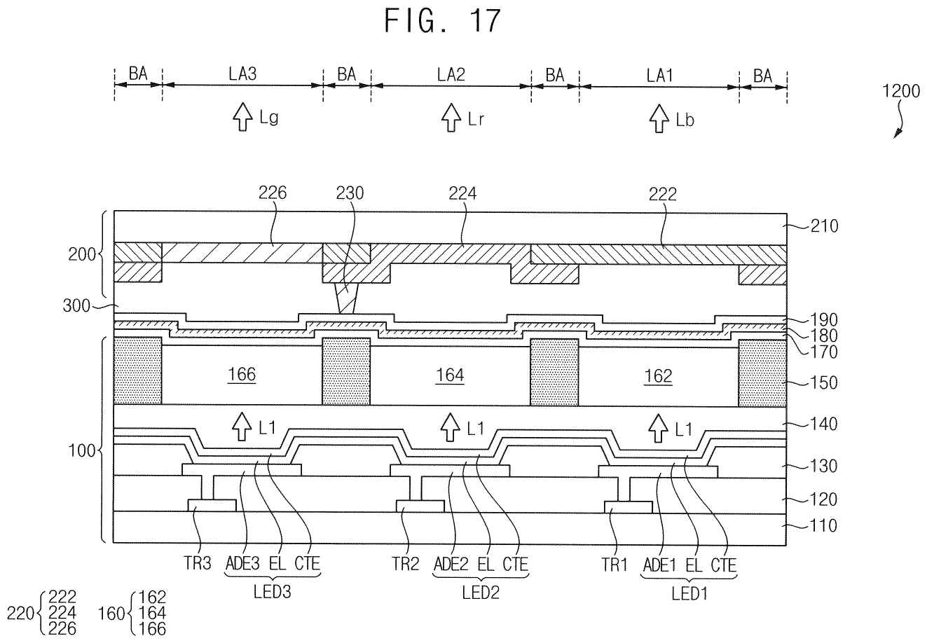

FIG. 16 is a cross-sectional view illustrating a display device according to an alternative embodiment. Particularly, FIG. 16 may correspond to the cross-sectional view of FIG. 4.

An embodiment of the display device 1100 shown in FIG. 16 may be substantially the same as embodiments of the display device 1000 described with reference to FIGS. 1 to 15 except for colors of light selectively transmitted by the second color filter 224 and the third color filter 226.

In an embodiment, as shown in FIG. 16, the first color filter 222 may be a blue color filter that selectively transmits the blue light Lb, and the second color filter 224 may be a green color filter that selectively transmits the green light Lg, and the third color filter 226 may be a red color filter that selectively transmits the red light Lr.

In such an embodiment, the first color conversion pattern 164 may convert incident light L1 generated from the second light emitting diode LED2 into the green light Lg. In an embodiment, for example, the first wavelength conversion particle of the first color conversion pattern 164 may include quantum dot that absorb blue light and emit green light. Also, the second color conversion pattern 166 may convert incident light L1 generated from the third light emitting diode LED3 into the red light Lr. In an embodiment, for example, the second wavelength conversion particle of the second color conversion pattern 166 may include quantum dot that absorb blue light and emit red light.

Accordingly, the first light emitting area LA1 may emit the blue light Lb, the second light emitting area LA2 may emit the red light Lr, and the third light emitting area LA3 may emit the green light Lg.

In such an embodiment, the spacer 230 may include a color filter composition including a red dye, a red pigment, including the red dye and/or the red pigment.

According to an embodiment, the third color filter 226 finally formed among the first to third color filters 222, 224, and 226 may be a red color filter. Accordingly, the efficiency of the process of forming the color filter layer 220 may be improved. Accordingly, the efficiency of the manufacturing process of the display device 1100 may be improved.

FIG. 17 is a cross-sectional view illustrating a display device according to another alternative embodiment. Particularly, FIG. 17 may correspond to the cross-sectional view of FIG. 4.

An embodiment of the display device 1200 shown in FIG. 17 may be substantially the same as embodiments of the display device 1000 described with reference to FIGS. 1 to 15 except for a refractive layer 180 and a second capping layer 190.

In an embodiment, as shown in FIG. 17, the lower structure 100 may further include the refractive layer 180 and the second capping layer 190. In such an embodiment, the refractive layer 240 and the second capping layer 250 of the upper structure 200 may be omitted. In such an embodiment, the refractive layer and the second capping layer may be included in the lower structure 100 instead of the upper structure 200.

In an embodiment, the refractive layer 180 may be disposed on the first capping layer 170 of the lower structure 100. In such an embodiment, the refractive layer 180 may be disposed to surround the first capping layer 170. In such an embodiment, the refractive layer 180 may be disposed to surround the bank 150 and the color conversion layer 160.

In an embodiment, the second capping layer 190 may be disposed on the refractive layer 180. In an embodiment, for example, the second capping layer 190 may be disposed to surround the refractive layer 180. In an alternative embodiment, the second capping layer 190 may be omitted.

According to embodiment, the refractive layer 180 is disposed on the lower structure 100, such that a gap between the lower structure 100 and the upper structure 200 may be reduced. Accordingly, display quality of the display device 1000 may be improved.

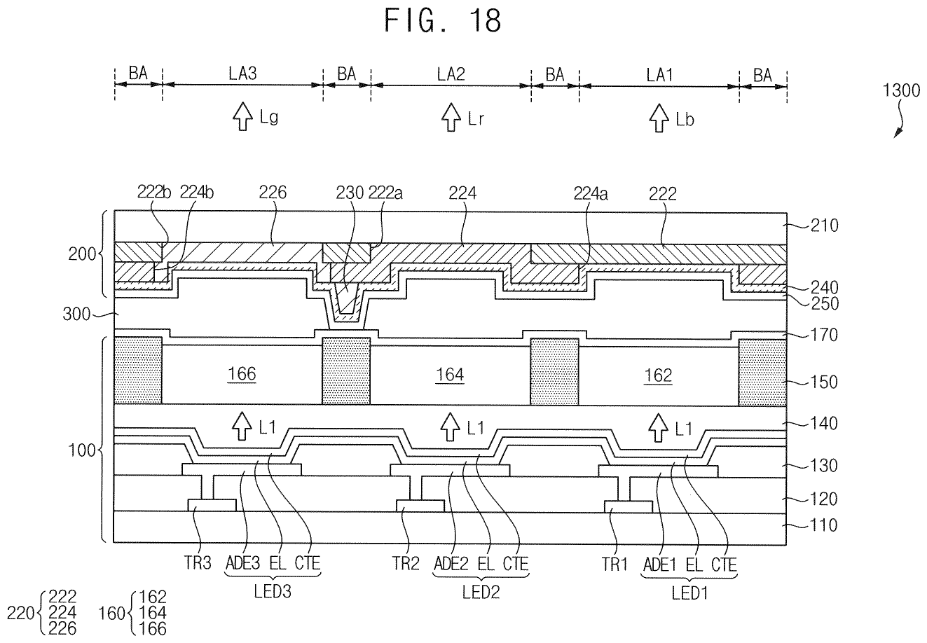

FIG. 18 is a cross-sectional view illustrating a display device according to still another embodiment. Particularly, FIG. 18 may correspond to the cross-sectional view of FIG. 4.

An embodiment of the display device 1300 shown in FIG. 18 may be substantially the same as embodiments of the display device 1000 described with reference to FIGS. 1 to 15 except for an arrangement of the third color filter 226.

In an embodiment, as shown in FIG. 18, the size of the fourth opening 224b may be greater than the size of the second opening 222b. In such an embodiment, in cross section, the width of the fourth opening 224b in the first direction D1 may be greater than the width of the second opening 222b in the first direction D1. In such an embodiment, the fourth opening 224b may expose a portion of the upper substrate 210 and a portion of the first color filter 222 together.

In such an embodiment, the third color filter 226 may be disposed to cover the first color filter 222 exposed through the fourth opening 224b. In other words, a portion of the third color filter 226 may overlap a portion of the first color filter 222 in the blocking area BA. Accordingly, color mixing between the adjacent first to third light emitting areas LA1, LA2, and LA3 may be further prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
an upper substrate;
a lower substrate disposed opposite to the upper substrate, wherein first to third light emitting areas and a light blocking area surrounding the first to third light emitting areas are defined on each of the upper substrate and the lower substrate;
a plurality of light emitting diodes disposed on the lower substrate;
a color conversion layer including a light transmission pattern disposed in the first light emitting area on the lower substrate, a first color conversion pattern disposed in the second light emitting area on the lower substrate, and a second color conversion pattern disposed in the third light emitting area on the lower substrate;
a color filter layer including a first color filter disposed in the first light emitting area and the light blocking area under the upper substrate, a second color filter disposed in the second light emitting area and the light blocking area under the upper substrate, and a third color filter disposed in the third light emitting area under the upper substrate and having an island pattern shape; and
a spacer disposed in the light blocking area between the color filter layer and the color conversion layer, wherein the spacer includes a same material as the third color filter.

2. The display device of claim 1, wherein the first color filter and the second color filter overlap each other in the light blocking area.

3. The display device of claim 1, wherein a planar shape of the third color filter is a polygonal, a rhombic, a circular, a track-shaped, or an elliptical planar shape.

4. The display device of claim 1, wherein a first opening and a second opening exposing a portion of the upper substrate are defined through the first color filter,
wherein a third opening exposing a portion of the first color filter and a fourth opening exposing a portion of the upper substrate and overlapping the second opening are defined through the second color filter, and
wherein the third color filter is disposed in the second opening.

5. The display device of claim 4, wherein the third color filter is spaced apart from the light blocking area.

6. The display device of claim 5, wherein the fourth opening exposes a portion of the second color filter, and
Wherein the third color filter is disposed to cover the portion of the second color filter exposed through the fourth opening.

7. The display device of claim 1, further comprising:
a thin film encapsulation layer disposed on the lower substrate and covering the plurality of light emitting diodes, and
wherein the color conversion layer is disposed on the thin film encapsulation layer to directly contact the thin film encapsulation layer.

8. The display device of claim 1, further comprising:
a refractive layer disposed to cover the color filter layer and the spacer.

9. The display device of claim 1, further comprising:
a capping layer disposed to cover the color conversion layer; and
a refractive layer disposed to cover the capping layer.

10. The display device of claim 1, wherein the first color filter is a blue color filter which selectively transmits blue light,
wherein the second color filter is a red color filter which selectively transmits red light, and
wherein the third color filter is a green color filter which selectively transmits green light.

11. The display device of claim 1, wherein the first color filter is a blue color filter which selectively transmits blue light,
wherein the second color filter is a green color filter which selectively transmits green light, and
wherein the third color filter is a red color filter which selectively transmits red light.

12. A method of manufacturing a display device, the method comprising:
providing a first color filter on an upper substrate, in which first to third light emitting areas and a light blocking area surrounding the first to third light emitting areas are defined, wherein the first color filter is disposed in the first light emitting area and the light blocking area;
providing a second color filter on the upper substrate, wherein the second color filter is disposed in the second light emitting area and the light blocking area;
providing a third color filter and a spacer on the upper substrate, wherein the third color filter is disposed in the third light emitting area and having an island pattern shape, and the spacer is disposed in the light blocking area;
providing a color conversion layer on a lower substrate, wherein the first to third light emitting areas and the light blocking area are defined in the lower substrate, and the color conversion layer includes a light transmission pattern disposed in the first light emitting area on the lower substrate, a first color conversion pattern disposed in the second light emitting area on the lower substrate, and a second color conversion pattern disposed in the third light emitting area on the lower substrate; and
bonding the upper substrate and the lower substrate to each other in a way such that the upper substrate is disposed opposite to the lower substrate.

13. The method of claim 12, wherein the spacer is formed of a same material as the third color filter.

14. The method of claim 12, wherein after the bonding the upper substrate and the lower substrate to each other, the spacer is disposed between the first and second color filters in the light blocking area and the color conversion layer.

15. The method of claim 12, wherein the first color filter and the second color filter overlap each other in the light blocking area.

16. The method of claim 12, wherein the third color filter has a polygonal, a rhombic, a circular, a track-shaped, or an elliptical planar shape.

17. The method of claim 12, wherein the first color filter is a blue color filter which selectively transmits blue light,
wherein the second color filter is a red color filter which selectively transmits red light, and
wherein the third color filter is a green color filter which selectively transmits green light.

18. The method of claim 17, wherein the first color filter is a blue color filter which selectively transmits blue light,
wherein the second color filter is a green color filter which selectively transmits green light, and
wherein the third color filter is a red color filter which selectively transmits red light.

19. The method of claim 12, further comprising:
providing a refractive layer to cover the third color filter and the spacer after the providing the third color filter and the spacer on the upper substrate.

20. The method of claim 12, further comprising:
providing a capping layer to cover the color conversion layer after the providing the third color filter and the spacer on the upper substrate; and
providing a refractive layer to cover the capping layer after the providing the capping layer.
